(19) United States
(12) Patent Application Publication
(10) Pub. No.: US 2005/0225206 A1
(43) Pub. Date: Oct. 13, 2005

(54) Multi-electrode piezoelectric ceramic

(76) Inventor: Michio Tsujiura, Shizuoka (JP)

Correspondence Address: ANDERSON, KILL & OLICK, P.C., 1251 AVENUE OF THE AMERICAS, NEW YORK,, NY, 10020-1182, US

(21) Appl. No.: 10/817,236

(22) Filed: Apr. 2, 2004

(51) Int. Cl. H01L 41/08

(52) U.S. Cl. 310/328

(57) ABSTRACT

A piezoelectric ceramic belt comprising a piezoelectric ceramic layer in the form of an endless belt having an upper surface and a lower surface with said layer further comprising a first set of circular or square electrodes formed on the upper surface of the belt with the electrodes arranged at regular intervals along the circumference of the belt and spaced a given distance from both side edges of the belt and a second set of circular or square electrodes formed on the lower surface of the belt aligned in position with said first set of electrodes on the upper surface of the belt wherein the electrodes of the first and second set are polarized by application of a high voltage to cause a piezoelectric effect in the ceramic layer between the electrodes in the first set acting as either positive or negative electrodes and the electrodes in the second set acting as counter electrodes.

### TECHNICAL FIELD

The present invention relates to piezoelectric ceramics.

### RELATED ART

Conventionally, each of the electrodes of a piezoelectric ceramic element is provided on the upper and lower surfaces thereof, i.e., only a given set of electrodes is provided for each element. As a result, functionality of a piezoelectric ceramic element has heretofore been limited in that it will respond to only one type of electrical command as provided through the one set of electrodes.

Sheet type piezoelectric ceramics have not been widely utilized in that it has become a matter of course to use the type of arrangement in which one piezoelectric ceramic element has only one set of electrodes despite the fact this type has a limited space for wiring.

The present invention provides for a piezoelectric ceramic belt having a piezoelectric ceramic layer preferably arranged as an endless belt with the upper and lower surfaces having many electrodes.

### BRIEF DESCRIPTION OF THE DRAWINGS

FIG. 1 is a perspective view illustrating the basic configuration of the present invention.

FIG. 2 is a partial perspective view of the present invention.

FIGS. 3A-3B illustrate a sheet type piezoelectric ceramic element in accordance with the present invention.

FIG. 4 is a partial perspective view of the present invention and

FIG. 5 is a perspective view of a further embodiment of the present invention.

### DETAILED DESCRIPTION OF THE INVENTION

FIG. 1 is a perspective view which illustrates the basic configuration of the present invention. Reference numeral 1 denotes a piezoelectric ceramic belt having a set of electrodes represented by reference numbers 2 and 3 which are provided on the outer and inner and circumferences respectively of the piezoelectric ceramic belt 1.

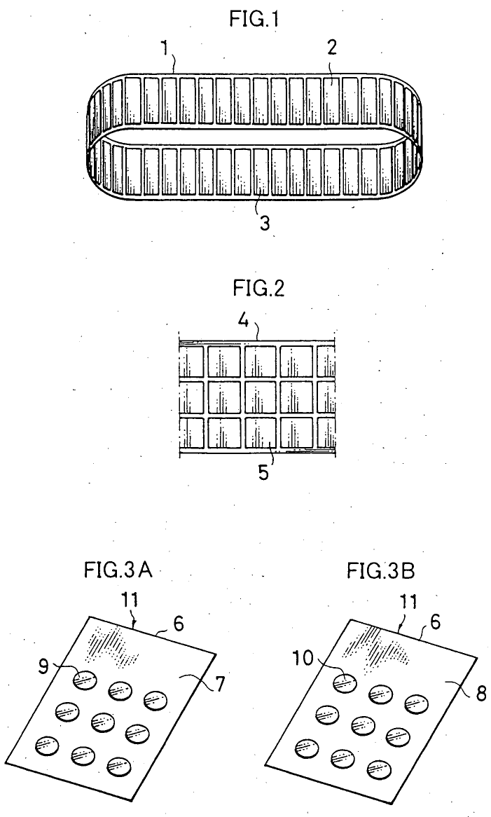

FIG. 2 illustrates a part of a piezoelectric ceramic belt 4 which is similar to the belt 1 of FIG. 1 having a set of electrodes 5 in the form of a multiple array with the set of electrodes 5 shown on one of the respective circumferences of the belt 4 with the understanding that a corresponding multiple array of electrodes (not shown) would be provided on the other opposing circumference of the belt 4 similar to that of FIG. 1.

FIGS. 3 A and B illustrate the upper and lower surface of a piezoelectric ceramic sheet 11 having on each surface thereof an array of multiple electrodes 9 and 10 of the same shape with the selected shape being any desired shape. FIG. 3A illustrates only the upper surface 7 of the ceramic sheet 11 having a multiple array of electrodes 9 whereas FIG. 3B illustrates the lower surface 8 of the piezoelectric ceramic sheet 11 having a corresponding number of multi-electrodes 10. The upper and lower surfaces 7 and 8 have complementary electrodes aligned in position relative to one another and form electrode pairs.

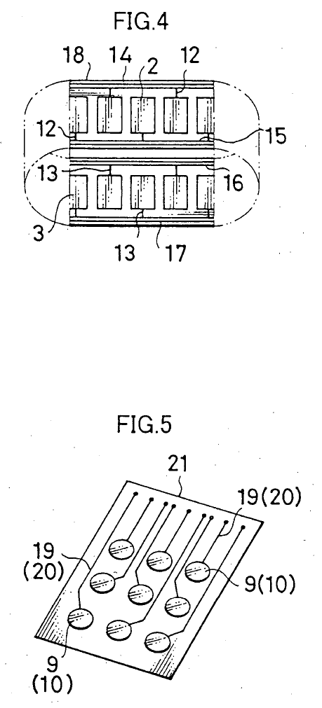

FIG. 4 is a partial perspective view of the piezoelectric ceramic belt embodiment of FIG. 1 in which each pair of electrodes on the upper and lower surfaces is polarized by applying a high voltage across the positive and negative electrodes for a sufficient time period of, e.g., between 15 to 30 minutes to create an electric dipole of ceramic particles between electrodes aligned in the same direction. The polarized piezoelectric ceramic belt 18 has a circuit formed between each electrode pair on the inner and outer circumferences of the belt respectively. Reference numeral 12 denotes a wire that is screen printed, post-print baked, or printed by a similar technique (hereinafter referred to as “screen printing”) on the outer circumference of the belt to connect to each electrode 2; whereas reference numeral 13 denotes another type of wire screen printed on the inner circumference of the belt to connect to each electrode 3 in a similar manner. The wires are provided on each ceramic surface of the belt. Reference numbers 14 and 15 represent collector wires screen printed with wire 12 and at the same time whereas reference numbers 16 and 17 are collector wires screen printed with wire 13 and at the same time.

FIG. 5 is a perspective view of the present invention illustrating a piezoelectric ceramic sheet having polarized multiple electrodes on opposite sides of the sheet. Reference numeral 9 (10) designates an electrode pair formed between the upper and lower surface of the sheet; Reference numeral 19 (20) designates a complementary printed wire screen for each electrode 9 (10); Reference numeral 21 constitutes the multi-electrode piezoelectric ceramic sheet which is not illustrated in this perspective view. Nonetheless, the wiring on the lower surface is provided in the same manner as that on the upper surface.

The electrodes on the inner and the outer circumferences of the belt type piezoelectric ceramic are of the same size and the same shape and are formed at a given pitch on the same points on opposite surfaces of the thin plate ceramic element. This provides the same advantageous effect as a large number of thin piezoelectric ceramic elements arranged in a continuous manner.

Because the thin flat type piezoelectric ceramic belt is itself a good insulator, when the electrode 2 on the inner circumference and the electrode 3 on the outer circumference are polarized by a high voltage applied therebetween, polarization effect is caused only in the piezoelectric ceramic layer sandwiched between the two electrodes to produce a piezoelectric element. The high voltage applied does not directly affect adjacent electrodes because they are spaced at a certain distance therefrom.

When multiple arrays of electrodes are provided on the inner and the outer circumference of piezoelectric ceramic belt 4, the high voltage applied to each electrode 5 for polarization does not affect other polarization process by application of a high voltage across the adjacent electrodes, as long as a certain distance is maintained between the electrodes 5 on the same surface. It is only the portion of the piezoelectric ceramic belt 4 between each electrode on the inner and the outer circumferences that turns into a piezoelectric element.

The ceramic surfaces of the piezoelectric ceramic sheet between the electrodes or where no electrode is provided show perfect insulating performance. Therefore printing wires on such ceramic surfaces does not cause any electrical problems, and it is rather preferable to utilize the ceramic surfaces for designing and configuring a electric circuit.

Wires 12 and 13 each connected to electrodes 2 and 3 on the outer and inner circumferences of the piezoelectric ceramic belt 18 and connector wires 14, 15, 16, and 17 that form a circuit with these wires are formed by printing such as screen printing so as to facilitate conducting to each electrode.

Similarly, conductive wires 19 and 20 connected to electrodes 9 and 10 on multi-electrode piezoelectric ceramic sheet 21 are formed by printing such as screen printing so as to facilitate conducting to each electrode.

1. A piezoelectric ceramic belt comprising a piezoelectric ceramic layer in the form of an endless belt having an upper surface and a lower surface with said layer further comprising:
a first set of circular or square electrodes formed on the upper surface of the belt with the electrodes arranged at regular intervals along the circumference of the belt and spaced a given distance from both side edges of the belt; and
a second set of circular or square electrodes formed on the lower surface of the belt aligned in position with said first set of electrodes on the upper surface of the belt;
wherein the electrodes of the first and second set are polarized by application of a high voltage to cause a piezoelectric effect in the ceramic layer between the electrodes in the first set acting as either positive or negative electrodes and the electrodes in the second set acting as counter electrodes.

2. A piezoelectric ceramic belt as set forth in claim 1 wherein said electrodes in the first and second set on the upper and the lower surfaces of the belt are arranged in plural lines along the circumference of the belt.

3. A piezoelectric ceramic belt as set forth in claim 1 wherein each set of electrodes is formed by screen printing.

4. A piezoelectric ceramic belt as set forth in claim 7 further comprising a wire formed on the upper surface of the piezoelectric ceramic belt for connecting the electrodes on the upper surface thereof, a wire formed on the lower surface of the piezoelectric ceramic belt for connecting the electrodes on the lower surface thereof and collector wires formed on the upper and the lower surfaces of the belt so that an electrical circuit is formed.

5. Multi-electrode piezoelectric ceramic sheet comprising:
a piezoelectric ceramic sheet having a piezoelectric ceramic layer,
a plurality of circular or square electrodes formed on both an upper surface and a lower surface of the piezoelectric ceramic sheet with the number of electrodes on can surface being equal in an arrangement with the electrodes on the upper surface aligned in position relative to electrodes on the lower surface, and
wherein the electrodes on the upper surface are arranged relative to the electrodes on the lower surface to form complementary electrode pairs such that upon application of a high voltage each pair of electrodes is polarized to cause a piezoelectric effect in the ceramic layer between each of the electrode pairs respectively and with the electrodes on the upper surface acting as either the positive or negative electrodes and the electrodes on the lower surface acting as counter electrodes.

6. Multi-electrode piezoelectric ceramic sheet as set forth in claim 5 further comprising a wire formed on said upper surface of the piezoelectric ceramic sheet by printing such as screen printing and baking to connect to the electrodes on the upper surface, and a wire formed on said lower surface of the piezoelectric ceramic sheet by printing such as screen printing and baking to connect to the electrodes on the lower surface.

7. A prezoelectric ceramic belt as set forth in claim 1 wherein the electrodes in the first and second set are equal in number with each set representing a multiple array of electrodes with the electrodes of each set arranged relative to one another to form a multiple number of complementary electrode pairs and wherein each of the electrode pairs are polarized by said high voltage to create an electric dipole of ceramic particles between the electrodes in each electrode pair.
